(19) United States
(12) Patent Application Publication
(10) Pub. No.: US 2015/0243816 A1
(43) Pub. Date: Aug. 27, 2015

(54) METHODS OF MAKING BARRIER ASSEMBLIES

(71) Applicants: Alan K. NACHTIGAL, (US); ANDREW T. RUFF, (US); CHRISTOPHER S. LYONS, (US); Guy D. JOLY, (US); Joseph C. SPAGNOLA, (US); Mark D. WEIGEL, (US); Michael D. DELMORE, (US); Samuel KIDANE, (US); Thomas P. KLUN, (US); 3M INNOVATIVE PROPERTIES COMPANY, SAINT PAUL, MN (US)

(72) Inventors: Aan K. Nachtigal, Minneapolis, MN (US); Andrew T. Ruff, Mendota Heights, MN (US); Christopher S. Lyons, Saint Paul, MN (US); Guy D. Joly, Shoreview, MN (US); Joseph C. Spagnola, Woodbury, MN (US); Mark D. Weigel, Hugo, MN (US); Michael D. Delmore, Grant, MN (US); Samuel Kidane, Saint Paul, MN (US); Thomas P. Lun, Lakeland, MN (US)

(21) Appl. No.: 14/421,030

(22) PCT Filed: Aug. 15, 2013
(86) PCT No.: PCT/US13/55035

§ 371 Date: Feb. 11, 2015

Related U.S. Application Data
(60) Provisional application No. 61/779,432, filed on Mar. 13, 2013.
(60) Provisional application No. 61/683,824, filed on Aug. 16, 2012.

(51) Int. Cl. H01L 31/048; B32B 37/12; B32B 37/10; H01L 51/44

(52) U.S. Cl. CPC H01L 31/0481; H01L 51/448; B32B 37/12; B32B 37/1018; B32B 2307/412; B32B 2307/7265; B32B 2307/40; B32B 2333/08; B32B 2307/546

(57) ABSTRACT

The present disclosure generally relates to methods of forming barrier assemblies. Some embodiments include application and removal of a protective layer followed by application of a topsheet. Some embodiments include application and removal of a protective layer including a release agent and a monomer.

### RELATED APPLICATIONS

This application claims the benefit under 35 U.S.C. §119(e) of U.S. Provisional Application No. 61/683,824 filed Aug. 16, 2012 and U.S. Provisional Application No. 61/779,432 filed Mar. 13, 2013.

### TECHNICAL FIELD

The present disclosure generally relates to methods of making barrier assemblies.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources.

One of the promising energy resources today is sunlight. Globally, millions of households currently obtain power from solar energy generation. The rising demand for solar power has been accompanied by a rising demand for devices and materials capable of fulfilling the requirements for these applications. Photo voltaic cells are a fast-growing segment of solar power generation.

Two specific types of photo voltaic cells—organic photo voltaic devices (OPVs) and thin film solar cells (e.g., copper indium gallium di-selenite (CIGS)) require protection from water vapor and need to be durable (e.g., to ultra-violet (UV) light) in outdoor environments. Glass is typically used for such solar devices because glass is a very good barrier to water vapor, is optically transparent, and is stable to UV light. However, glass is heavy, brittle, difficult to make flexible, and difficult to handle. Transparent flexible encapsulating materials are being developed to replace glass. Preferably, these materials have glass-like barrier properties and UV stability. These flexible barrier films are desirable for electronic devices whose components are sensitive to the ingress of water vapor, such as, for example, flexible thin film and organic photo voltaic solar cells and organic light emitting diodes (OLEDs).

Some exemplary barrier films of this general type include multilayer stacks of polymers and oxides deposited on flexible plastic films to make high barrier films resistant to moisture permeation. Examples of these barrier films are described in U.S. Pat. Nos. 5,440,446; 5,877,895; 6,010,751; U.S. Pat. Apl. Pub. No. 2003/0029493; and 66737US002, all of which are incorporated herein by reference as if fully set forth herein.

### SUMMARY

The inventors of the present application recognized that under certain conditions multilayer stacks of polymers and oxides may suffer degradation in adhesion performance after extended exposure to moisture, possibly causing these high barrier stacks to delaminated at the oxide-polymer interface.

The inventors of the present disclosure recognized that application of and subsequent removal of a temporary protective layer to the oxide layer creates an improved barrier assembly. In some embodiments, the protective layer is applied to the oxide layer to protect the oxide layer during processing. Inclusion of the protective layer during processing reduces defect formation in the oxide layer. In some embodiments, the protective layer is subsequently removed from the oxide layer during downstream processing.

Some methods of making an improved barrier assembly involve providing a substrate; applying a polymeric material adjacent to the substrate to form a polymer layer; applying an oxide-containing material adjacent to the polymer layer to form an oxide layer; applying a protective material adjacent to the oxide layer to form a protective layer; removing the protective layer; and applying a topsheet.

In some embodiments, the topsheet can include an adhesive. In some embodiments, the adhesive is a pressure sensitive adhesive.

In some embodiments, the steps of applying a polymeric material and applying an oxide-containing material are repeated sequentially numerous times to form a barrier assembly having numerous alternating polymer layers and oxide layers. In some embodiments, the protective layer includes at least one of a (meth)acrylate monomer and/or oligomer. In some embodiments, the protective layer includes at least one of urethane (meth)acrylate, isobornyl (meth)acrylate, dipentacrythritol penta(meth)acrylate, epoxy (meth)acrylate, epoxy (meth)acrylates blended with styrene, di-trimethylolpropane tetra(meth)acrylate, diethylene glycol di(meth)acrylate, 1,3-butylene glycol di(meth)acrylate, penta(meth)acrylate esters, pentaerythritol tetra(meth)acrylate, pentaerythritol tri(meth)acrylate, ethoxylated (3) trimethylolpropane tri(meth)acrylate, ethoxylated (3) trimethylolpropane tri(meth)acrylate, alkoxylated trifunctional (meth)acrylate esters, dipropylene glycol di(meth)acrylate, neopentyl glycol di(meth)acrylate, ethoxylated (4) bisphenol di(meth)crylate, cyclohexane dimethanol di(meth)acrylate esters, isobornyl (meth)acrylate, cyclic di(meth)acrylates, tris (2-hydroxy ethyl)isocyanurate tri(meth)acrylate, and (meth)acrylate compounds (e.g. oligomers or polymers) formed from the foregoing acrylates and methacrylates.

In some embodiments, removing the protective layer involves at least one of chemical removal, mechanical removal, and optical removal. In some embodiments, removing the protective layer involves at least one of chemical dissolution and reaction. In some embodiments, removing the protective layer involves at least one of peeling, scraping, and use of a mechanical removal device. In some embodiments, the protective layer is a multilayer construction and includes an adhesive layer. In some embodiments, the protective material is applied adjacent to the oxide layer in a vacuum. In some embodiments, the barrier assembly is flexible and light transmissive.

In some embodiments, the method further comprises applying a release agent adjacent to the oxide layer to form a release agent layer. In some embodiments, the release agent layer is applied before the protective layer is applied. In some embodiments, the release agent layer includes a silane.

In some embodiments, the method further comprises forming a continuous roll of barrier assembly. In some embodiments, the protective layer includes a release agent and a monomer.

Some embodiments are optical devices including a barrier assembly as described herein. Some embodiments are photo voltaic modules including a barrier assembly as described herein.

Some embodiments are methods of making a barrier assembly involving providing a substrate; applying a polymeric material adjacent to the substrate to form a polymer layer; applying an oxide containing material adjacent to the polymer layer to form an oxide layer; applying a protective material adjacent to the oxide layer to form a protective layer; and removing the protective layer. In these embodiments, the protective layer includes a release agent and a monomer.

Some embodiments further comprise applying a topsheet adjacent to the oxide layer after removing the protective layer. In some embodiments, the topsheet includes an adhesive material. In some embodiments, the adhesive material is a pressure sensitive adhesive.

In some embodiments, the steps of applying a polymeric material and applying an oxide-containing material are repeated sequentially numerous times to form a barrier assembly having numerous alternating polymer layers and oxide layers. In some embodiments, the protective layer includes at least one of a (meth)acrylate monomer and/or oligomer. In some embodiments, the protective layer includes at least one of urethane (meth)acrylate, isobornyl (meth)acrylate, dipentaaerythritol penta(meth)acrylate, epoxy (meth)acrylate, epoxy (meth)acrylates blended with styrene, di-trimethylolpropane tetra(meth)acrylate, diethylene glycol di(meth)acrylate, 1,3-butylene glycol di(meth)acrylate, penta(meth)acrylate esters, pentaerythritol tetra(meth)acrylate, pentaerythritol tri(meth)acrylate, ethoxylated (3) trimethylolpropane tri(meth)acrylate, ethoxylated (3) trimethylolpropane tri(meth)acrylate, alkoxylated trifunctional (meth)acrylate esters, dipropylene glycol di(meth)acrylate, neopentyl glycol di(meth)acrylate, ethoxylated (4) bisphenol a di(meth)crylate, cyclohexane dimethanol di(meth)acrylate esters, isobornyl (meth)acrylate, 1,10-decanediol diacrylate, 1,6 hexanediol diacrylate, 1,9 nonanediol diacrylate, 1,12 dodecanediol diacrylate, cyclic di(meth)acrylates, tris (2-hydroxy ethyl)isocyanurate tri(meth)acrylate, and (meth)acrylate compounds (e.g. oligomers or polymers) formed from the foregoing acrylates and methacrylates.

In some embodiments, removing the protective layer involves at least one of chemical removal, mechanical removal, and optical removal. In some embodiments, removing the protective layer involves at least one of chemical dissolution and reaction. In some embodiments, removing the protective layer involves at least one of peeling, scraping, and use of a mechanical removal device. In some embodiments, the protective layer is a multilayer construction and includes an adhesive layer. In some embodiments, the protective material is applied adjacent to the oxide layer in a vacuum. In some embodiments, the barrier assembly is flexible and light transmissive.

In some embodiments, the method further comprises applying a release agent adjacent to the oxide layer to form a release agent layer. In some embodiments, the release agent layer is applied before the protective layer is applied. In some embodiments, the release agent layer includes a silane.

In some embodiments, the method further comprises forming a continuous roll of barrier assembly. In some embodiments, the protective layer includes a release agent and a monomer.

Some embodiments are optical devices including a barrier assembly as described herein. Some embodiments are photo voltaic modules including a barrier assembly as described herein.

In some exemplary embodiments, flexible electronic devices can be encapsulated directly with the methods described herein. For example, the devices can be attached to a flexible carrier substrate, and a mask can be deposited to protect electrical connections from the inorganic layer(s), (co)polymer layer(s), or other layer(s)s during their deposition. The inorganic layer(s), (co)polymeric layer(s), and other layer(s) making up the multilayer barrier assembly can be deposited as described elsewhere in this disclosure, and the mask can then be removed, exposing the electrical connections.

In one exemplary direct deposition or direct encapsulation embodiment, the moisture sensitive device is a moisture sensitive electronic device. The moisture sensitive electronic device can be, for example, an organic, inorganic, or hybrid organic/inorganic semiconductor device including, for example, a photo voltaic device such as a copper indium gallium (di)selenite (CIGS) solar cell; a display device such as an organic light emitting display (OLED), electrochromic display, electrophoretic display, or a liquid crystal display (LCD) such as a quantum dot LCD display; an OLED or other electroluminescent solid state lighting device, or combinations thereof and the like.

Examples of suitable processes for making a multilayer barrier assembly and suitable transparent multilayer barrier coatings can be found, for example, in U.S. Pat. No. 5,440,446 (Shaw et al.); U.S. Pat. No. 5,877,895 (Shaw et al.); U.S. Pat. No. 6,010,751 (Shaw et al.); and U.S. Pat. No. 7,018,713 (Padiyath et al.). In one presently preferred embodiment, the barrier assembly in an article or film can be fabricated by deposition of the various layers onto the substrate, in a roll-to-roll vacuum chamber similar to the system described in U.S. Pat. No. 5,440,446 (Shaw et al.) and U.S. Pat. No. 7,018,713 (Padiyath, et al.).

Other features and advantages of the present application are described or set forth in the following detailed specification that is to be considered together with the accompanying drawings.

### BRIEF DESCRIPTION OF DRAWINGS

The disclosure may be more completely understood in consideration of the following detailed description of various embodiments of the disclosure in connection with the accompanying drawings, in which:

FIGS. 1A-1D schematically show the sequential steps of one exemplary method of the present disclosure.

### DETAILED DESCRIPTION

In the following detailed description, reference may be made to the accompanying set of drawings that form a part hereof and in which are shown by way of illustration several specific embodiments. It is to be understood that other embodiments are contemplated and may be made without departing from the scope or spirit of the present disclosure.

At least some embodiments of the barrier assemblies described herein are transmissive to visible and infrared light. The term “transmissive to visible and infrared light” as used herein means having an average transmission over the visible and infrared portion of the spectrum of at least about 75% (in some embodiments at least about 80, 85, 90, 92, 95, 97, or 98%) measured along the normal axis. In some embodiments, the barrier assembly has an average transmission over a range of 400 nm to 1400 nm of at least about 75% (in some embodiments at least about 80, 85, 90, 92, 95, 97, or 98%). Typically, visible and infrared light-transmissive assemblies do not interfere with absorption of visible and infrared light, for example, by photo voltaic cells. In some embodiments, the visible and infrared light-transmissive assembly has an average transmission over a range of wavelengths of light that are useful to a photo voltaic cell of at least about 75% (in some embodiments at least about 80, 85, 90, 92, 95, 97, or 98%). The layers in the barrier assembly can be selected based on refractive index and thickness to enhance transmission to visible and infrared light.

In at least some embodiments, the barrier assemblies described herein are flexible. The term “flexible” as used herein refers to being capable of being formed into a roll. In some embodiments, the barrier assembly is capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the barrier assembly can be bent around a radius of curvature of at least 0.635 cm (¼ inch), 1.3 cm (½ inch) or 1.9 cm (¾ inch).

Barrier assemblies according to the present disclosure generally do not exhibit delamination or curl that can arise from thermal stresses or shrinkage in a multilayer structure. Herein, curl is measured using a curl gauge described in “Measurement of Web Curl” by Ronald P. Swanson presented in the 2006 AWEB conference proceedings (Association of Industrial Metallizers, Coaters and Laminators, Applied Web Handling Conference Proceedings, 2006). According to this method, curl can be measured to the resolution of 0.25 m⁻¹ curvature. In some embodiments, barrier assemblies according to the present disclosure exhibit curls of up to 7, 6, 5, 4, or 3 m⁻¹. From solid mechanics, the curvature of a beam is known to be proportional to the bending moment applied to it. The magnitude of bending stress in turn is known to be proportional to the bending moment. From these relations the curl of a sample can be used to compare the residual stress in relative terms. Barrier assemblies also typically exhibit high peel adhesion to EVA, and other common encapsulants for photovoltaics, cured on a substrate. The properties of the barrier assemblies disclosed herein typically are maintained even after high temperature and humidity aging.

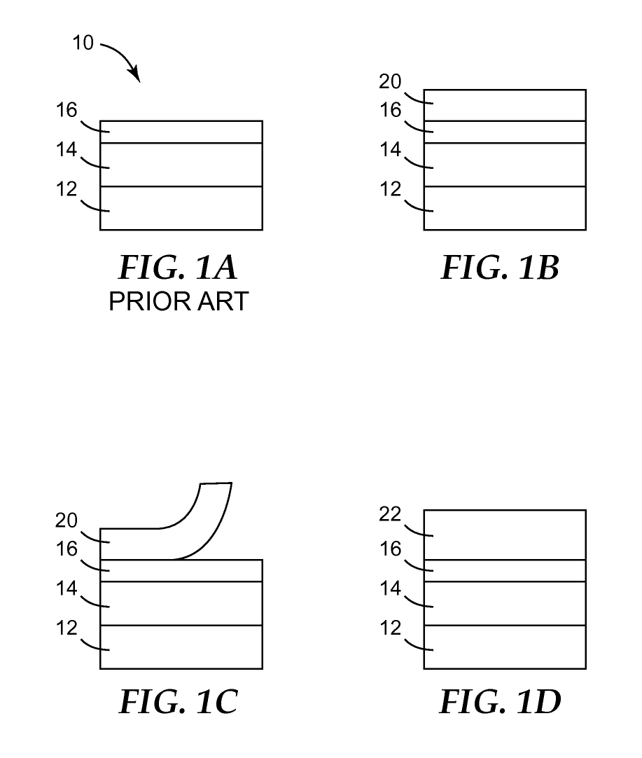

A prior art barrier assembly 10 as shown in FIG. 1A is formed by providing a substrate 12; applying a polymeric material adjacent to a major surface of substrate 12 to form a polymer layer 14; and applying an oxide-containing material adjacent to a major surface of polymer layer 14 to form an oxide layer 16. Although only one polymer layer (14) and one inorganic layer (16) are shown, barrier assemblies of the type described and claimed herein can include additional alternating layers of polymer and oxide. Exemplary materials and construction methods for barrier assembly 10 are identified in U.S. Pat. Nos. 5,440,446; 5,877,895; 6,010,751; U.S. Pat. App. Pub. No. 2003/0029493; 69821US002, and 66737US002 (all of which are herein incorporated by reference as if fully set forth herein) and in the Examples of the present disclosure. As used herein, the term “polymeric” will be understood to include organic homopolymers and copolymers, as well as polymers or copolymers that may be formed in a miscible blend, for example, by co-extrusion or by reaction, including transesterification. The terms “polymer” and “copolymer” include both random and block copolymers.

In one embodiment of the present application shown schematically in FIG. 1B, a protective material is applied adjacent to a major surface of oxide layer 16 to form a protective layer 20. Protective material/protective layer 20 reduces defect formation in the oxide layer during manufacturing. Protective material/protective layer 20 protects the oxide layer from damage during vacuum web handling and subsequent process steps. As shown schematically in FIG. 1C, protective layer 20 is removed. As shown in the exemplary embodiment of FIG. 1C, protective layer 20 is removed by peeling it off of oxide layer 16. This is only one exemplary removal method and the scope of the present disclosure should in no way be limited to the exemplary embodiment depicted schematically in FIG. 1C.

In some embodiments and as shown schematically in FIG. 1D, following removal of protective layer 20, a topsheet 22 is applied adjacent to a major surface of oxide layer 16. In some embodiments, topsheet 22 is a multilayer construction that includes an adhesive layer (not shown).

In some embodiments, materials for use in the protective layer include any material that does not enhance the adhesion of the protective layer to the oxide layer. In some embodiments, the protective layer comprises a single layer. In other embodiments, the protective layer includes a plurality of layers.

Some exemplary materials for use in the protective layer include any (co)polymer suitable for deposition in a thin film. In some embodiments, the protective layer can include one or more of the following materials: (meth)acrylate monomers and/or oligomers that include acrylates or methacrylates such as urethane (meth)acrylates, isobornyl (meth)acrylate, dipentaaerythritol penta(meth)acrylate, epoxy (meth)acrylates, epoxy (meth)acrylates blended with styrene, di-trimethylolpropane tetra(meth)acrylate, diethylene glycol di(meth)acrylate, 1,3-butylene glycol di(meth)acrylate, penta(meth)acrylate esters, pentaerythritol tetra(meth)acrylate, pentaerythritol tri(meth)acrylate, ethoxylated (3) trimethylolpropane tri(meth)acrylate, ethoxylated (3) trimethylolpropane tri(meth)acrylate, alkoxylated trifunctional (meth)acrylate esters, dipropylene glycol di(meth)acrylate, neopentyl glycol di(meth)acrylate, ethoxylated (4) bisphenol a di(meth)crylate, cyclohexane dimethanol di(meth)acrylate esters, isobornyl (meth)acrylate, cyclic di(meth)acrylates, tris (2-hydroxy ethyl)isocyanurate tri(meth)acrylate, 1,10-decanediol diacrylate, 1,6 hexanediol diacrylate, 1,9 nonanediol diacrylate, 1,12 dodecanediol diacrylate, and (meth)acrylate compounds (e.g. oligomers or polymers) formed from the foregoing acrylates and methacrylates.

In some embodiments, the protective layer also includes release agents. Some exemplary materials used as or in release agents include silicones, fluorinated materials (e.g., monomers, oligomers, or polymers containing fluoroalkyl or fluoroalkylene or perfluoropolyether moieties), soluble materials, solvent degradable materials, alkyl chains (e.g., straight, branched, and/or cyclic hydrocarbon moieties containing 12-36 carbon atoms), and the like.

Soluble materials are typically solvent or water soluble liquids and/or solids. Exemplary soluble materials for use as or in release agents include hydrocarbon materials (e.g., paraffin, natural and polyethylene waxes) and water soluble compounds (e.g., soaps, detergents).

In some embodiments, the protective layer includes a monomer in addition to the release agent. Some exemplary monomers include (meth)acrylate monomers and/or oligomers that include acrylates or methacrylates such as urethane (meth)acrylates, isobornyl (meth)acrylate, dipentaaerythritol penta(meth)acrylate, epoxy (meth)acrylates, epoxy (meth)acrylates blended with styrene, di-trimethylolpropane tetra(meth)acrylate, diethylene glycol di(meth)acrylate, 1,3-butylene glycol di(meth)acrylate, penta(meth)acrylate esters, pentaerythritol tetra(meth)acrylate, pentaerythritol tri(meth)acrylate, ethoxylated (3) trimethylolpropane tri(meth)acrylate, ethoxylated (3) trimethylolpropane tri(meth)acrylate, alkoxylated trifunctional (meth)acrylate esters, dipropylene glycol di(meth)acrylate, neopentyl glycol di(meth)acrylate, ethoxylated (4) bisphenol a di(meth)crylate, cyclohexane dimethanol di(meth)acrylate esters, isobornyl (meth)acrylate, cyclic di(meth)acrylates, tris (2-hydroxy ethyl) isocyanurate tri(meth)acrylate, and (meth)acrylate compounds (e.g. oligomers or polymers) formed from the foregoing acrylates and methacrylates.

In some embodiments, the protective layer is a masking film. As used herein, the term “masking film” means a film or paper that adheres to the oxide layer. The masking film may be corona-treated or coated with adhesive such as a pressure sensitive adhesion to facilitate adhesion. Upon removal it is desired that the masking material leaves minimal residue on the oxide layer. Some exemplary masking film materials include ethylene, polyethylene, polypropylene, polyethylene terephthalate. For example polyethylene tape 3M 2104C, polyester acrylic tape 3M 1614C, or masking films commercially available from Tredegar Corporation, Toray Industries and others.

In some embodiments, the protective layer is a soluble and/or swellable protective layer. Exemplary soluble materials for use in the protective layer include polymers (e.g., carboxy methyl cellulose, polyacrylic acid, polyvinyl alcohol, and polyethyleneoxide-containing polymer) and positive and negative-acting photoresists.

Deposition of the protective layer can be accomplished in any desired way. For example, the protective layer can be applied as a monomer or oligomer and cross-linked to form a (co)polymer in situ (e.g., by flash evaporation and vapor deposition of a radiation-crosslinkable monomer, followed by crosslinking using, for example, an electron beam apparatus, UV light source, electrical discharge apparatus or other suitable device). In some embodiments, the protective layer material (e.g., monomer, oligomer, or copolymer) can be applied using conventional coating methods such as roll coating (e.g., gravure roll coating) or spray coating (e.g., electrostatic spray coating). In some embodiments, the protective layer can then be crosslinked. In some embodiments, the protective layer can be formed by applying a layer containing an oligomer or (co)polymer in solvent and drying the thus-applied layer to remove the solvent. In some embodiments, chemical vapor deposition (CVD) may also be employed. In some embodiments, the protective layer can be formed by flash evaporation and vapor deposition followed optionally by crosslinking in situ, e.g., as described in U.S. Pat. No. 4,696,719 (Bischoff), U.S. Pat. No. 4,722,515 (Ham), U.S. Pat. No. 4,842,893 (Yializis et al.), U.S. Pat. No. 4,954,371 (Yializis), U.S. Pat. No. 5,018,048 (Shaw et al.), U.S. Pat. No. 5,032,461(Shaw et al.), U.S. Pat. No. 5,097,800 (Shaw et al.), U.S. Pat. No. 5,125,138 (Shaw et al.), U.S. Pat. No. 5,440,446 (Shaw et al.), U.S. Pat. No. 5,547,908 (Furuzawa et al.), U.S. Pat. No. 6,045,864 (Lyons et al.), U.S. Pat. No. 6,231,939 (Shaw et al. and U.S. Pat. No. 6,214,422 (Yializis). Where the protective layer is a masking film, the protective layer can be adhered or attached to the oxide layer by placing the film directly adjacent to the oxide layer. In some embodiments, any of the methods described above are done as an in-line process. In some embodiments, any of the application methods described above are done in vacuum.

In some exemplary embodiments, flexible electronic devices can be encapsulated directly with the methods described herein. For example, the devices can be attached to a flexible carrier substrate, and a mask can be deposited to protect electrical connections from the inorganic layer(s), (co)polymer layer(s), or other layer(s)s during their deposition. The inorganic layer(s), (co)polymeric layer(s), and other layer(s) making up the multilayer barrier assembly can be deposited as described elsewhere in this disclosure, and the mask can then be removed, exposing the electrical connections.

In one exemplary direct deposition or direct encapsulation embodiment, the moisture sensitive device is a moisture sensitive electronic device. The moisture sensitive electronic device can be, for example, an organic, inorganic, or hybrid organic/inorganic semiconductor device including, for example, a photo voltaic device such as a copper indium gallium (di)selenite (CIGS) solar cell; a display device such as an organic light emitting display (OLED), electrochromic display, electrophoretic display, or a liquid crystal display (LCD) such as a quantum dot LCD display; an OLED or other electroluminescent solid state lighting device, or combinations thereof and the like.

Examples of suitable processes for making a multilayer barrier assembly and suitable transparent multilayer barrier coatings can be found, for example, in U.S. Pat. No. 5,440,446 (Shaw et al.); U.S. Pat. No. 5,877,895 (Shaw et al.); U.S. Pat. No. 6,010,751 (Shaw et al.); and U.S. Pat. No. 7,018,713 (Padiyath et al.). In one presently preferred embodiment, the barrier assembly in an article or film can be fabricated by deposition of the various layers onto the substrate, in a roll-to-roll vacuum chamber similar to the system described in U.S. Pat. No. 5,440,446 (Shaw et al.) and U.S. Pat. No. 7,018,713 (Padiyath, et al.).

Protective layer removal can be accomplished in any desired way. For example, the protective layer can be removed mechanically, chemically, optically, thermally, or a combination thereof. One exemplary chemical removal process involves dissolution of a soluble protective layer. Another exemplary chemical removal process involves reaction of the protective layer. Yet another exemplary chemical removal process involves swellability of the protective layer. One exemplary removal process involves a negative or positive-acting photoresist, as generally known in the art. One exemplary optical removal method involves application of a protective layer that is highly absorbing in a designated light range and removing the protective layer by exposing the protective layer to irradiance in that light range that causes dissolution of the protective layer. One exemplary mechanical removal process involves peeling the protective layer off. Another exemplary mechanical removal method involves using a mechanical tool or removal device to remove the protective layer (e.g., scraping). Another exemplary mechanical removal process includes spraying the protective layer. Other exemplary removal techniques are chemical or plasma etching. In some embodiments, any of the methods described above are done as an in-line process. In some embodiments, any of the removal methods described above are done in vacuum.

In some embodiments, a release agent is applied to the oxide layer before the protective material is applied to form a release agent layer (not shown). In other embodiments the release agent is co-deposited with the protective layer on the oxide layer. Exemplary release agent layers include silicones, fluorinated materials (e.g., monomers, oligomers, or polymers containing fluoroalkyl or fluoroalkylene or perfluoropolyether moieties), soluble materials, alkyl chains (e.g., straight, branched, and/or cyclic hydrocarbon moieties containing 12-36 carbon atoms), and the like.

Any topsheet material can be used in the embodiments of the present application. In some embodiments, the topsheet is adhered to the barrier film by means of a pressure sensitive adhesive. Useful materials that can form the topsheet include polyacrylates, polyesters, polycarbonates, polyethers, polyimides, polyolefins, fluoropolymers, and combinations thereof. Exemplary materials for use in the topsheet include those listed in U.S. Patent Application Publication No. 2012/0003448 (Weigel et al), incorporated by reference herein in its entirety.

In some embodiments, stabilizers are added to the topsheet to improve its resistance to UV light. In some embodiments, stabilizers are added to the pressure sensitive adhesive. Examples of such stabilizers include at least one of ultra violet absorbers (UVA) (e.g., red shifted UV absorbers), hindered amine light stabilizers (HALS), or anti-oxidants. Other exemplary include those listed in U.S. Patent Application Publication No. 2012/0003448 (Weigel et al), incorporated by reference herein in its entirety.

In some embodiments, the protective layer is removed from the oxide layer immediately prior to downstream attachment of a topsheet to the oxide layer.

At least some embodiments of the barrier films or assemblies made using the processes described herein have high optical transmission of 85% or higher. At least some embodiments of the barrier films or assemblies made using the processes described herein have low water vapor transmission rates of 0.005 g/m2-day or lower at 50° C. and 100% RH. Additionally, at least some embodiments of the barrier films or assemblies made using the processes described herein are highly durable and maintain interlayer adhesion when exposed to external stresses such as, for example, UV light, thermal cycling, and moisture ingress.

In some embodiments, the barrier film can be fabricated by deposition of the various layers onto the substrate in a roll-to-roll vacuum chamber described in or similar to the system described in U.S. Pat. No. 5,440,446 (Shaw et al.) and U.S. Pat. No. 7,018,713 (Padiyath, et al.), both of which are incorporated herein in their entirety.

Some advantages of the methods of the present disclosure include, for example, enablement of low-cost, continuous, roll-to-roll processing. Additionally, the use of a temporary protective layer allows the creation of a barrier assembly with fewer interfaces because it removed the protective layer from the final barrier assembly product. Fewer interfaces may lead to decreased risk of adhesive failure between interfaces. In instances where the prior art protective layer was susceptible to adhesion loss, the removal of this protective layer from the final construction may result in a barrier assembly with increased weatherability and longevity. The presence of a temporary protective layer during processing reduces the incidence of particulate contamination during processing/manufacturing. Also, the presence of a temporary protective layer during processing protects the oxide layer from damage or contamination during processing and handling.

In one embodiment, the barrier assembly of the present disclosure is used in a photo voltaic module. The photo voltaic module includes a backsheet; a solar cell; and a barrier assembly made according to the method of any of the preceding claims.

In some embodiments, the barrier assembly of the present disclosure is used in an optical device, optical display device, or solid state lighting device. One exemplary optical device is an organic light emitting diode (OLED).

### EXAMPLES

Preparation of Comparative Laminate Constructions A-B and Laminate Constructions 1-3

Comparative Laminate Constructions A-B and Laminate Constructions 1-3 were prepared by using a 0.05 mm thick pressure sensitive adhesive (PSA) (obtained under the trade designation “3M OPTICALLY CLEAR ADHESIVE 8172P” from 3M Company, St. Paul, Minn.) to laminate 22.9 cm by 15.2 cm barrier films to an ethylene tetrafluoroethylene polymer sheet (ETFE) (0.05 mm thick, available under the trade designation “NORTON ETFE”, from St. Gobain Performance Plastics, Wayne, N.J.), with the top coat polymer layer of the barrier film adjacent the ETFE sheet. Comparative Laminate Constructions A-B and Laminate Constructions 1-3 were prepared using barrier films of, respectively, Comparative Examples A-B, and Examples 1-3. The polyethylene terephthalate (PET) side of the barrier film was then placed on the polytetrafluoroethylene (PTFE) side of a 0.14 mm (0.0056 in) thick 21.6 cm by 14 cm PTFE-coated aluminum foil (obtained under the trade designation “8656K61”, from McAlester-Carr, Santa Fe Springs, Calf.). The PTFE-coated aluminum foil was 1.27 cm smaller than the barrier film in each dimension, thus leaving a portion of the PET exposed. A 13 mm (0.5 in) wide desiccated edge tape (obtained under the trade designation “SOLARGAIN EDGE TAPE SET LP01” from Trussed Technologies Inc., Solon, Ohio) was placed around the perimeter of the PTFE-coated aluminum foil to secure the laminated barrier sheet to the PTFE layer. A 0.38 cm (0.015 in) thick encapsulants film (obtained under the trade designation “JURASOL” from JuraFilms, Downer Grove, Ill.) was placed on the aluminum side of the PTFE-coated aluminum foil. The PET layer of a second laminated barrier sheet, identical in composition to the first laminated barrier sheet, was disposed over the encapsulants film, to form a laminate construction. The construction was vacuum laminated at 150° C. for 12 min.

### TEST METHODS

Spectral Transmission

Spectral transmission was measured using a spectrometer (model “LAMBDA 900”, commercially available from PerkinElmer, Waltham, Mass.). Spectral transmission is reported as average percent transmission (Tvis) between 400 nm and 700 nm at a 0° angle of incidence.

Water Vapor Transmission Rate

Water vapor transmission rate (WVTR) of the barrier films of Comparative Examples A-B and Examples 1-3 was measured in accordance with the procedure outlined in ASTM F-1249-06, “Standard Test Method for Water Vapor Transmission Rate Through Plastic Film and Sheeting Using a Modulated Infrared Sensor” using a MOCON PERMATRAN-W® Model 700 WVTR testing system (obtained from MOCON, Inc, Minneapolis, Minn.). Temperature of about 50° C. and relative humidity (RH) of about 100% were used and WVTR is expressed in grams per square meter per day (g/m2/day). The lowest detection limit of the testing system was 0.005 g/m2/day. In some instances, the measured WVTR was below the lowest detection limit and is reported as <0.005 g/m2/day.

Aging Test

Comparative Laminate Constructions A-B and Laminate Constructions 1-3 were placed in an environmental chamber (model “SE-1000-3”, obtained from Thermotron Industries, Holland, Mich.) set to a temperature of about 85° C. and relative humidity of about 85%, for 0 (initial), 250, 500 and 1000 hours.

T-Peel Test Method

Aged and unaged barrier films of Comparative Examples A-B and Examples 1-3 were removed from the laminate construction by peeling off the PTFE layer. The barrier films were then cut into 1.0 in wide (2.54 cm) sections. These sections were placed in a tensile strength tester (obtained under the trade designation “INISIGHT 2 SL” with Testworks 4 software from MTS, Eden Prairie, Minn.), following the procedure outlined in ASTM D 1876-08 “Standard Test Method for Peel Resistance of Adhesives (T-Peel Test).” A peel speed of 254 mm/min (10 inches/min) was used. Adhesion is reported in Newton per centimeter (N/cm) as the average of four peel measurements between 0.05 and 5.95 inches of extension. In some instances, T-peel adhesion was not measured and is reported as “N/M”.

### Comparative Example A

Barrier films were prepared by covering a polyetheylene teraphthalate (PET) substrate film (obtained from E. I. DuPont de Nemours, Wilmington, Del., under the trade name “XST 6642”) with a stack of an base polymer layer, an inorganic silicon aluminum oxide (SiAlOx) barrier layer, and an protective polymer layer on a vacuum coater similar to the coater described in U.S. Pat. No. 5,440,446(Shaw et al.) and U.S. Pat. No. 7,018,713 (Padiyath, et al), both of which are incorporated herein by reference. The individual layers were formed as follows:

The polymer layer: a 280 meter long roll of 0.127 mm thick×366 mm wide PET film was loaded into a roll-to-roll vacuum processing chamber. The chamber was pumped down to a pressure of 1×10⁻⁵ Torr. A web speed of 4.9 meter/min was held while maintaining the backside of the PET film in contact with a coating drum chilled to −10° C. With the backside in contact with the drum, the film frontside surface was treated with a nitrogen plasma at 0.02 kW of plasma power. The film frontside surface was then coated with tricyclodecane dimethanol diacrylate monomer (obtained under the trade designation “SR-833S”, from Sartomer USA, Exton, Pa.). The monomer was degassed under vacuum to a pressure of 20 mTorr prior to coating, loaded into a syringe pump, and pumped at a flow rate of 1.33 mL/min through an ultrasonic atomizer operating at a frequency of 60 kHz into a heated vaporization chamber maintained at 260° C. The resulting monomer vapor stream condensed onto the film surface and was electron beam crosslinked using a multi-filament electron-beam cure gun operating at 7.0 kV and 4 mA to form a 720 nm thick base polymer layer.

Layer 2 (inorganic layer): immediately after the base polymer layer deposition and with the backside of the PET film still in contact with the drum, a SiAlOx layer was sputter-deposited atop a 23 m length of the base polymer layer. Two alternating current (AC) power supplies were used to control two pairs of cathodes; with each cathode housing two 90% Si/10% Al sputtering targets (obtained from Materion Corporation, Mayfield Heights, Ohio). During sputter deposition, the voltage signal from each power supply was used as an input for a proportional-integral-differential control loop to maintain a predetermined oxygen flow to each cathode. The AC power supplies sputtered the 90% Si/10% Al targets using 5000 watts of power, with a gas mixture containing 850 standard cubic centimeter per minute (sccm) argon and 94 sccm oxygen at a sputter pressure of 3.2 millitorr. This provided a 24 nm thick SiAlOx layer deposited atop the base polymer layer of Layer 1.

Layer 3 (protective polymer layer): immediately after the SiAlOx layer deposition and with the backside of the PET film still in contact with the drum, the acrylate monomer (same monomer of Layer 1) was condensed onto Layer 2 and crosslinked as described in Layer 1, except that (i) prior to being loaded into the syringe pump the degassed tricyclodecane dimethanol diacrylate monomer was mixed with N-n-butyl-aza-2,2-dimethoxysilacyclopentane (commercially available from Gelest, Inc., Morrisville, Pa. under the trade designation “Cyclic AZA Silane 1932.4”), the mixture containing 3 weight % (wt %) of the cyclic AZA silane and 97 wt % of the acrylate monomer; and (ii) a multi-filament electron-beam cure gun operating at 7 kV and 5 mA was used. This provided a 720 nm thick protective polymer layer atop Layer 2.

The indicator paper placed in the laminate construction prepared as described above using the barrier films of Comparative Example A, remained blue (i.e., no water ingress detected) through 1000 hours during the aging test.

Initial T-peel adhesion, spectral transmission (Tvis) and water vapor transmission rate (WVTR) of the barrier film of Comparative Example A were measured using the test methods described above. The barrier film was then aged, following the procedure outlined above, for 500 and 1000 hours. T-peel adhesion was measured for the aged sample. Results are reported in Table 1, below.

### Comparative Example B

A barrier film was prepared as described in Comparative Example A, with the exception that only Layer 1 and Layer 2 were formed, resulting in a two-layer stack.

The indicator paper placed in the laminate construction prepared as described above using the barrier films of Comparative Example B, turned white (i.e., water ingress detected) after 250 hours during the aging test.

Initial T-peel adhesion, spectral transmission (Tvis) and water vapor transmission rate (WVTR) of the barrier film of Comparative Example B were measured using the test methods described above. The barrier film was then aged, following the procedure outlined above, for 500 and 1000 hours. T-peel adhesion was measured for the aged sample. Results are reported in Table 1, below.

### Example 1

A barrier film was prepared as described in Comparative Example B, with the exception that the protective layer (Layer 3) comprised a polyester acrylic tape (commercially available from 3M Company, Saint Paul, Minn.; under the trade designation “3M PROTECTIVE POLYESTER TAPE 1614C CLEAR”). This multi-layer construction was crosslinked using the electron beam cure gun of Comparative Example A, and the protective layer (Layer 3) was subsequently removed to form a two-layer barrier film.

The indicator paper placed in the laminate construction prepared as described above using the barrier films of Example 1, remained blue (i.e., no water ingress detected) through 1000 hours during the aging test.

Initial T-peel adhesion, spectral transmission (Tvis) and water vapor transmission rate (WVTR) of the barrier film of Example 1 were measured using the test methods described above. The barrier film was then aged, following the procedure outlined above, for 500 and 1000 hours. T-peel adhesion was measured for the aged sample. Results are reported in Table 1, below.

### Example 2

A barrier film was prepared as described in Comparative Example A, with the following exceptions: (i) Layer 3 (protective layer) comprised 100 wt % degassed tricyclodecane dimethanol diacrylate monomer; (ii) the acrylate monomer was pumped at a flow rate of 2.66 ml/min, providing an optically hazy protective acrylate layer having a thickness of about 1440 nm; and (iii) after crosslinking, the three layer stack was laminated to a “NORTON ETFE” polymer sheet using the “3M OPTICALLY CLEAR ADHESIVE 8172P”, followed by subsequent mechanical removal of the ETFE, PSA and protective layer (Layer 3), resulting in a two-layer barrier film.

The indicator paper placed in the laminate construction prepared as described above using the barrier films of Example 1, remained blue (i.e., no water ingress detected) through 1000 hours during the aging test.

Initial T-peel adhesion, spectral transmission (Tvis) and water vapor transmission rate (WVTR) of the barrier film of Example 1 were measured using the test methods described above. The barrier film was then aged, following the procedure outlined above, for 500 and 1000 hours. T-peel adhesion was measured for the aged sample. Results are reported in Table 1, below.

### Example 3

A barrier film was prepared as described in Example 2, with the exception that the tricyclodecane dimethanol diacrylate monomer was replaced with decanediol diacrylate (DDDA) (commercially available from TCI Co., Montgomeryville, Pa., under the trade designation “1,10-Bis(acryloyloxy)decane”).

A two-layer barrier film was prepared as described in Example 2.

The indicator paper placed in the laminate construction prepared as described above using the barrier films of Example 1, remained blue (i.e., no water ingress detected) through 1000 hours during the aging test.

Initial T-peel adhesion, spectral transmission (Tvis) and water vapor transmission rate (WVTR) of the barrier film of Example 1 were measured using the test methods described above. The barrier film was then aged, following the procedure outlined above, for 500 and 1000 hours. T-peel adhesion was measured for the aged sample. Results are reported in Table 1, below.

TABLE 1
Performance Characteristics of Exemplary Barrier Assemblies

| | Spectral | | T-peel adhesion (N/cm) | | |
|---|---|---|---|---|---|
| | Transmission | WVTR | Initial | 500 | 1000 |
| Examples | (%) | (g/m2/day) | (0 hours) | hours | hours |
| Comparative | 87 | <0.005 | 6.1 | 8.9 | 0.7 |
| Example A | | | | | |
| Comparative | 87 | 0.06 | 10.3 | 10.2 | 10.9 |
| Example B | | | | | |
| Example 1 | 87 | <0.005 | 10.6 | 10.2 | N/M |
| Example 2 | 87 | <0.005 | 10.4 | N/M | 11.1 |
| Example 3 | 87 | <0.005 | 10.6 | 10.8 | 11.1 |

All references mentioned herein are incorporated by reference.

As used herein, the words “on” and “adjacent” cover both a layer being directly on and indirectly on something, with other layers possibly being located therebetween.

As used herein, the terms “major surface” and “major surfaces” refer to the surface(s) with the largest surface area on a three-dimensional shape having three sets of opposing surfaces.

Unless otherwise indicated, all numbers expressing feature sizes, amounts, and physical properties used in the present disclosure and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise.

As used in this disclosure and the appended claims, the term “or” is generally employed in its sense including “and/or” unless the content clearly dictates otherwise.

The phrases “at least one of ” and “comprises at least one of ” followed by a list refers to any one of the items in the list and any combination of two or more items in the list. All numerical ranges are inclusive of their endpoints and non-integral values between the endpoints unless otherwise stated.

Various embodiments and implementation of the present disclosure are disclosed. The disclosed embodiments are presented for purposes of illustration and not limitation. The implementations described above and other implementations are within the scope of the following claims. One skilled in the art will appreciate that the present disclosure can be practiced with embodiments and implementations other than those disclosed. Those having skill in the art will appreciate that many changes may be made to the details of the above-described embodiments and implementations without departing from the underlying principles thereof. It should be understood that this invention is not intended to be unduly limited by the illustrative embodiments and examples set forth herein and that such examples and embodiments are presented by way of example only with the scope of the invention intended to be limited only by the claims set forth herein as follows. Further, various modifications and alterations of the present invention will become apparent to those skilled in the art without departing from the spirit and scope of the present disclosure. The scope of the present application should, therefore, be determined only by the following claims.

1. A method of forming a barrier assembly, comprising:
providing a substrate;
applying a polymeric material adjacent to the substrate to form a polymer layer;
applying an oxide-containing material adjacent to the polymer layer to form an oxide layer;
applying a protective material adjacent to the oxide layer to form a protective layer;
removing the protective layer; and
applying a topsheet.

2. The method of claim 1, wherein the topsheet includes an adhesive material.

3. The method of claim 2, wherein the adhesive material further includes a UV absorber.

4. The method of claim 2, wherein the adhesive material is a pressure sensitive adhesive.

5. (canceled)

6. The method of claim 1, wherein the protective layer includes at least one of (meth)acrylate monomers and/or oligomers.

7. (canceled)

8. (canceled)

9. (canceled)

10. (canceled)

11. (canceled)

12. The method of claim 1, wherein the protective material is applied adjacent to the oxide layer in a vacuum.

13. The method of claim 1, wherein the barrier assembly is flexible and light transmissive.

14. The method of claim 1, further comprising:
applying a release agent adjacent to the oxide layer to form a release agent layer.

15. (canceled)

16. (canceled)

17. (canceled)

18. The method of claim 1, wherein the protective layer includes a release agent and a monomer.

19. (canceled)

20. A photo voltaic module, comprising:
a barrier assembly made according to the method described in claim 1.

21. A method of forming a barrier assembly, comprising:
providing a substrate;
applying a polymeric material adjacent to the substrate to form a polymer layer;
applying an oxide-containing material adjacent to the polymer layer to form an oxide layer;
applying a protective material adjacent to the oxide layer to form a protective layer; and
removing the protective layer;
wherein the protective layer includes a release agent and a monomer.

22. The method of claim 21, further comprising:
applying a topsheet adjacent to the oxide layer after removing the protective layer.

23. The method of claim 22, wherein the topsheet includes an adhesive material.

24. The method of claim 23, wherein the adhesive material is a pressure sensitive adhesive.

25. (canceled)

26. The method of claim 21, wherein the protective layer includes at least one of (meth)acrylate monomers and/or oligomers.

27. (canceled)

28. (canceled)

29. (canceled)

30. (canceled)

31. (canceled)

32. The method of claim 21, wherein the protective material is applied adjacent to the oxide layer in a vacuum.

33. The method of claim 21, wherein the barrier assembly is flexible and light transmissive.

34. The method of claim 21, further comprising:
applying a release agent adjacent to the oxide layer to form a release agent layer.

35. (canceled)

36. (canceled)

37. (canceled)

38. The method of claim 21, wherein the protective layer includes a release agent and a monomer.

39. (canceled)

40. A photo voltaic module, comprising:
a barrier assembly made according to the method described in claim 21.
